(19) United States
(12) Patent Application Publication
(10) Pub. No.: US 2018/0040801 A1
(43) Pub. Date: Feb. 8, 2018

(54) PIEZOELECTRIC MATERIAL MEMBER CAPABLE OF GENERATING DIFFERENT FREQUENCIES AND TRANSDUCER THEREWITH

(71) Applicant: National Taiwan University of Science and Technology, Taipei City (TW)

(72) Inventors: Yu-Hsi Huang, Yilan County (TW); Ching-Kong Chao, Taipei City (TW); Li-Wen Wu, Kaohsiung City (TW); Ching-Min Hsu, Tainan City (TW)

(21) Appl. No.: 15/361,089

(22) Filed: Nov. 25, 2016

(30) Foreign Application Priority Data
Aug. 8, 2016 (TW) 105125129

(51) Int. Cl. H01L 41/047; B06B 1/06; H01L 41/113

(52) U.S. Cl. CPC H01L 41/0471; H01L 41/1132; B06B 1/0644

(57) ABSTRACT

A piezoelectric material member includes a piezoelectric body, an upper electrode and a lower electrode. The upper electrode and the lower electrode are disposed on different sides of the piezoelectric body. The upper electrode has a first upper electrode section and a second upper electrode section separated from the first upper electrode section. The lower electrode has a first lower electrode section and a second lower electrode section separated from the first lower electrode section. The first lower electrode section is coupled to the first upper electrode section, so that the piezoelectric body generates a first frequency via the first lower electrode section and the first upper electrode section. The second lower electrode section is coupled to the second upper electrode section, so that the piezoelectric body generates a second frequency via the second lower electrode section and the second upper electrode section.

### BACKGROUND OF THE INVENTION

### 1. Field of the Invention

The present invention relates to a piezoelectric material member and a transducer therewith, and more particularly, to a piezoelectric material member capable of generating different frequencies and a transducer therewith.

### 2. Description of the Prior Art

Recently, ultrasonic transducers are widely used in industry and medicine, such as to detect material defects or used as internal body disease detection, and so on. The ultrasonic probe is equipped with a piezoelectric ceramic member. The piezoelectric ceramic member emits an ultrasonic wave resulting from vibration with high frequency when the piezoelectric ceramic member is driven by an alternating voltage. When the ultrasonic wave encounters a barrier (such as a material defect or a disease inside the body), the ultrasonic wave is reflected by the barrier, and therefore results in an echo wave. When the echo wave returns to the piezoelectric ceramic member, the piezoelectric ceramic member will generate a current subjected to the echo wave, so that the system determines the size and the position of the barrier according to the current.

In general, the ultrasonic wave with high frequency is adapted for detecting shallow defects, while the ultrasonic wave with low frequency wave is adapted for detecting deep defects. Furthermore, the ultrasonic wave with high frequency has short wavelengths, resulting in that it is utilized for detecting small size defects, while the ultrasonic wave with low frequency has long wavelengths, resulting in that it fails to detect small size defects. However, the piezoelectric ceramic member in the conventional ultrasonic transducer can only generate a single operating frequency. Therefore, it is not able to deal with detection of shallow/deep defects as well as defects with small size by utilizing one single ultrasonic transducer, which reduces the applicability of the ultrasonic transducer.

### SUMMARY OF THE INVENTION

The present invention provides a piezoelectric material member capable of generating different vibration frequencies for solving above drawbacks.

According to an embodiment of the present invention, a piezoelectric material member capable of generating different vibration frequencies includes a piezoelectric body, an upper electrode and a lower electrode. The piezoelectric body has an upper side and a lower side opposite to the upper side. The upper electrode is disposed on the upper side. The upper electrode has a first upper electrode section and a second upper electrode section separated from the first upper electrode section. The lower electrode is disposed on the lower side. The lower electrode has a first lower electrode section and a second lower electrode section separated from the first lower electrode section. The first lower electrode section is coupled to the first upper electrode section, so that the piezoelectric body generates a first frequency via the first lower electrode section and the first upper electrode section. The second lower electrode section is coupled to the second upper electrode section, so that the piezoelectric body generates a second frequency via the second lower electrode section and the second upper electrode section.

According to another embodiment of the present invention, the first upper electrode section and the second upper electrode section are segmented by a first upper segmenting line, and the first lower electrode section and the second lower electrode section are segmented by a first lower segmenting line.

According to another embodiment of the present invention, the piezoelectric body is substantially a rectangular structure. The rectangular structure has a first upper long edge, a second upper long edge, a first upper short edge, a second upper short edge, a first lower long edge, a second lower long edge, a first lower short edge and a second lower short edge. The first upper long edge, the second upper long edge, the first upper short edge and the second upper short edge define the upper side. The first lower long edge, the second lower long edge, the first lower short edge and the second lower short edge define the lower side. The first upper segmenting line connects the first upper short edge and the second upper short edge, and the first lower segmenting line connects the first lower short edge and the second lower short edge.

According to another embodiment of the present invention, the first upper segmenting line is substantially perpendicular to the first upper short edge and the second upper short edge, and the first lower segmenting line is substantially perpendicular to the first lower short edge and the second lower short edge.

According to another embodiment of the present invention, the piezoelectric body is substantially a rectangular structure. The rectangular structure has a first upper long edge, a second upper long edge, a first upper short edge, a second upper short edge, a first lower long edge, a second lower long edge, a first lower short edge and a second lower short edge. The first upper long edge, the second upper long edge, the first upper short edge and the second upper short edge define the upper side. The first lower long edge, the second lower long edge, the first lower short edge and the second lower short edge define the lower side. The first upper segmenting line connects the first upper long edge and the second upper long edge, and the first lower segmenting line connects the first lower long edge and the second lower long edge.

According to another embodiment of the present invention, the first upper segmenting line is substantially perpendicular to the first upper long edge and the second upper long edge, and the first lower segmenting line is substantially perpendicular to the first lower long edge and the second lower long edge.

According to another embodiment of the present invention, the upper electrode further has a third upper electrode section and a fourth upper electrode section. The first upper electrode section, the second upper electrode section, the third upper electrode section and the fourth upper electrode section are separated from one another. The lower electrode further has a third lower electrode section and a fourth lower electrode section. The first lower electrode section, the second lower electrode section, the third lower electrode section and the fourth lower electrode section are separated from one another. The third lower electrode section is coupled to the third upper electrode section, so that the piezoelectric body generates a third frequency via the third lower electrode section and the third upper electrode section. The fourth lower electrode section is coupled to the fourth upper electrode section, so that the piezoelectric body generates a fourth frequency via the fourth lower electrode section and the fourth upper electrode section.

According to another embodiment of the present invention, the first upper electrode section, the second upper electrode section, the third upper electrode section and the fourth upper electrode section are segmented by a first upper segmenting line and a second upper segmenting line, and the first lower electrode section, the second lower electrode section, the third lower electrode section and the fourth lower electrode section are segmented by a first lower segmenting line and a second lower segmenting line.

According to another embodiment of the present invention, the piezoelectric body is substantially a rectangular structure. The rectangular structure has a first upper long edge, a second upper long edge, a first upper short edge, a second upper short edge, a first lower long edge, a second lower long edge, a first lower short edge and a second lower short edge. The first upper long edge, the second upper long edge, the first upper short edge and the second upper short edge define the upper side. The first lower long edge, the second lower long edge, the first lower short edge and the second lower short edge define the lower side. The first upper segmenting line connects the first upper long edge and the second upper long edge. The second upper segmenting line connects the first upper short edge and the second upper short edge. The first lower segmenting line connects the first lower long edge and the second lower long edge. The second lower segmenting line connects the first lower short edge and the second lower short edge.

According to another embodiment of the present invention, the first upper segmenting line is substantially perpendicular to the first upper long edge and the second upper long edge. The second upper segmenting line is substantially perpendicular to the first upper short edge and the second upper short edge. The first lower segmenting line is substantially perpendicular to the first lower long edge and the second lower long edge. The second lower segmenting line is substantially perpendicular to the first lower short edge and the second lower short edge. The first upper segmenting line is substantially perpendicular to the second upper segmenting line. The first lower segmenting line is substantially perpendicular to the second lower segmenting line.

According to another embodiment of the present invention, a transducer includes a housing, a piezoelectric material member, a first signal wire set and a second signal wire set. The piezoelectric material member is disposed inside the housing and includes a piezoelectric body, an upper electrode and a lower electrode. The piezoelectric body has an upper side and a lower side opposite to the upper side. The upper electrode is disposed on the upper side. The upper electrode has a first upper electrode section and a second upper electrode section separated from the first upper electrode section. The lower electrode is disposed on the lower side. The lower electrode has a first lower electrode section and a second lower electrode section separated from the first lower electrode section. The first lower electrode section corresponds to the first upper electrode section. The second lower electrode section corresponds to the second upper electrode section. The first signal wire set is coupled to the first upper electrode section and the first lower electrode section, so that the piezoelectric body generates a first frequency via the first lower electrode section and the first upper electrode section. The second signal wire set is coupled to the second upper electrode section and the second lower electrode section, so that the piezoelectric body generates a second frequency via the second lower electrode section and the second upper electrode section.

According to another embodiment of the present invention, the first signal wire set includes a first high potential voltage wire and a first low potential voltage wire. The first high potential voltage wire is electrically connected to the first upper electrode section. The first low potential voltage wire is electrically connected to the first lower electrode section. The second signal wire set includes a second high potential voltage wire and a second low potential voltage wire. The second high potential voltage wire is electrically connected to the second lower electrode section. The second low potential voltage wire is electrically connected to the second upper electrode section.

According to another embodiment of the present invention, the transducer further includes a gel body and a covering layer. The gel body is disposed inside the housing and for fixing the piezoelectric material member, the first signal wire set and the second signal wire set inside the housing. The covering layer is for covering the housing.

In summary, the present invention may apply a first alternating voltage to the first upper electrode section and the first lower electrode section of the piezoelectric material member via the first signal wire set, so that the piezoelectric body of the piezoelectric material member generates the first frequency (e.g., a low frequency) via the first lower electrode section and the first upper electrode section for detecting deep defects of a detected object. In addition, the present invention may apply a second alternating voltage to the second upper electrode section and the second lower electrode section of the piezoelectric material member via the second signal wire set, so that the piezoelectric body of the piezoelectric material member generates the second frequency (e.g., a high frequency) via the second lower electrode section and the second upper electrode section for detecting shallow defects of the detected object. As a result, the transducer of the present invention can simultaneously detect the deep and shallow defects of the detected object, which results in greatly enhancement of the applicability of the transducer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a sectional diagram of a transducer according to an embodiment of the present invention.

FIG. 2 is a diagram of a piezoelectric material member according to the first embodiment of the present invention.

FIG. 3 is a diagram of the piezoelectric material member in another view according to the first embodiment of the present invention.

FIG. 4 is an impedance-frequency diagram of the piezoelectric material member according to the first embodiment of the present invention.

FIG. 5 is a diagram of a piezoelectric material member according to a second embodiment of the present invention.

FIG. 6 is a diagram of the piezoelectric material member in another view according to the second embodiment of the present invention.

FIG. 7 is an impedance-frequency diagram of the piezoelectric material member according to the second embodiment of the present invention.

FIG. 8 is a diagram of a piezoelectric material member according to a third embodiment of the present invention.

FIG. 9 is a diagram of the piezoelectric material member in another view according to the third embodiment of the present invention.

FIG. 10 is an impedance-frequency diagram of the piezoelectric material member according to the third embodiment of the present invention.

### DETAILED DESCRIPTION

In the following detailed description of the embodiments, reference is made to the accompanying drawings which form a part hereof, and in which is shown by way of illustration specific embodiments in which the invention may be practiced. In this regard, directional terminology, such as “top,” “bottom,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” and “installed” and variations thereof herein are used broadly and encompass direct and indirect connections and installations. Accordingly, the drawings and descriptions will be regarded as illustrative in nature and not as restrictive.

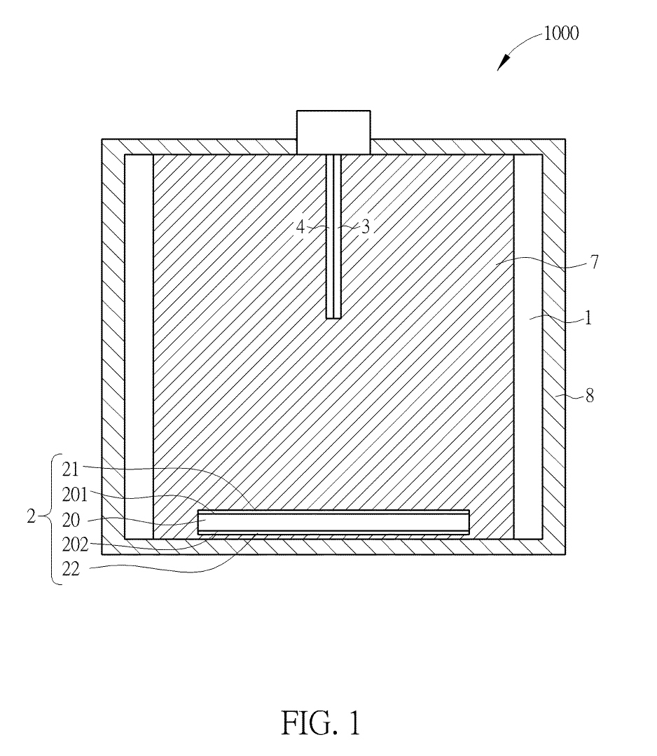

FIG. 1 is a sectional diagram of a transducer 1000 according to an embodiment of the present invention. As shown in FIG. 1, the transducer 1000 includes a housing 1, a piezoelectric material member 2, a first signal wire set 3, a second signal wire set 4, a gel body 7 and a covering layer 8. The piezoelectric material member 2 is disposed inside the housing 1 and has a piezoelectric body 20, an upper electrode 21 and a lower electrode 22. The piezoelectric body 20 has an upper side 201 and a lower side 202 opposite to the upper side 201. The upper electrode 21 is disposed on the upper side 201, and the lower electrode 22 is disposed on the lower side 202. The gel body 7 is disposed inside the housing 1 and for fixing the piezoelectric material member 2, the first signal wire set 3 and the second signal wire set 4 in the housing 1. The covering layer 8 is for covering the housing 1.

In this embodiment, the transducer 1000 can be an ultrasonic probe for detecting internal defects of an object or for detecting internal body disease and so on. The piezoelectric body 20 can be a piezoelectric ceramic piece. The upper electrode 21 and the lower electrode 22 can be made of chromium-gold alloy material. The gel body 7 can be made of epoxy resin material. The housing 1 may be made of metal material, such as copper. The housing 1 is used for shielding the piezoelectric material member 2, the 1, and the gel body 7 may be made of an epoxy resin material. The gel body 7 is used not only for fixing the piezoelectric material member 2, but also for insulating the piezoelectric material member 2 from the housing 1. The covering layer 8 is used not only for covering and protecting the housing 1, but also for insulating the housing 1 from surroundings thereof.

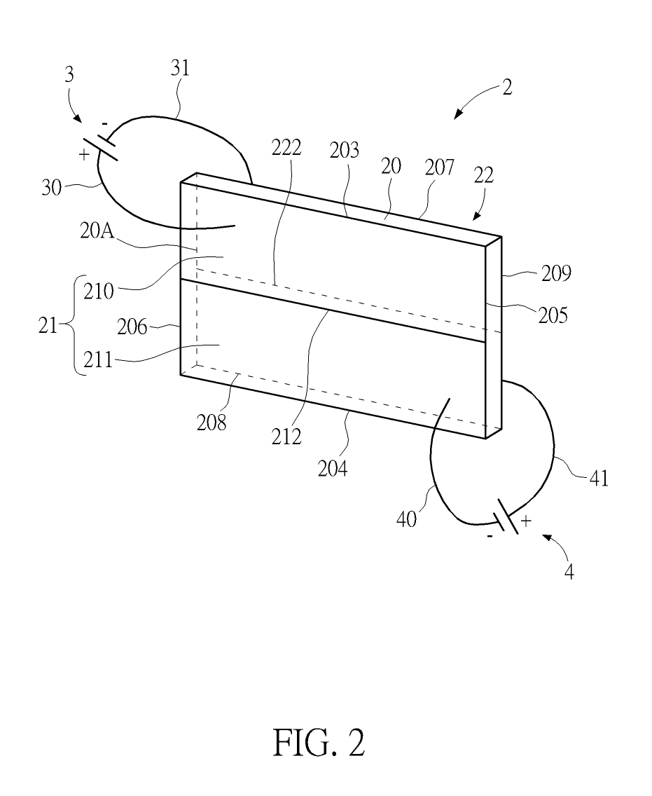

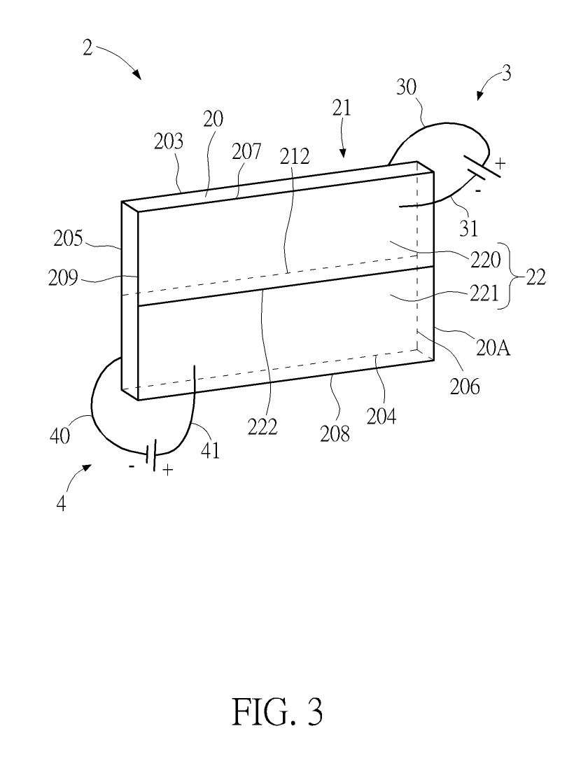

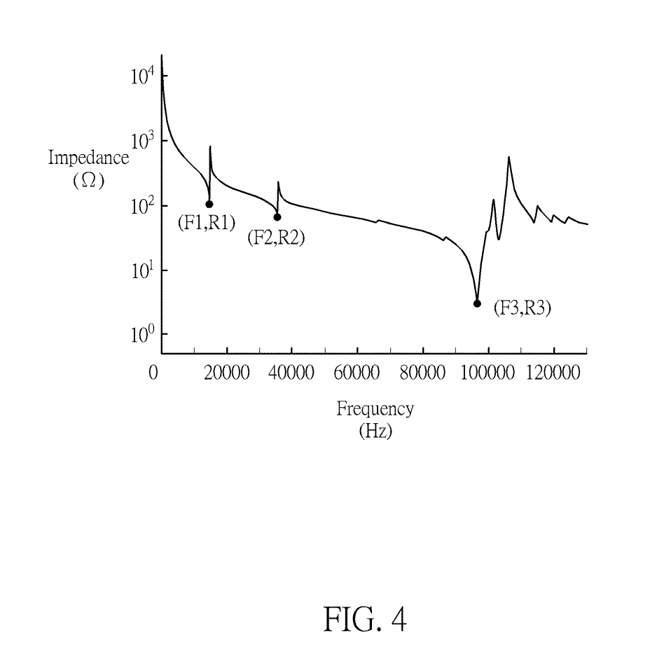

Please refer to FIG. 2 to FIG. 4. FIG. 2 is a diagram of the piezoelectric material member 2 according to the first embodiment of the present invention. FIG. 3 is a diagram of the piezoelectric material member 2 in another view according to the first embodiment of the present invention. FIG. 4 is an impedance-frequency diagram of the piezoelectric material member 2 according to the first embodiment of the present invention. As shown in FIG. 2 to FIG. 4, the upper electrode 21 of the piezoelectric material member 2 has a first upper electrode section 210 and a second upper electrode section 211 separated from the first upper electrode section 210. The first upper electrode section 210 and the second upper electrode section 211 segmented by a first upper segmenting line 212. The lower electrode 22 has a first lower electrode section 220 and a second lower electrode section 221 separated from the first lower electrode section 220. The first lower electrode section 220 corresponds to the first upper electrode section 210, and the second lower electrode section 221 corresponds to the second upper electrode section 211, wherein the first lower electrode section 220 and the second lower electrode section 221 are segmented by a first lower section 222.

Furthermore, the first signal wire set 3 includes a first high potential voltage wire 30 and a first low potential voltage wire 31. The first high potential voltage wire 30 is electrically connected to the first upper electrode section 210, and the first low potential voltage wire 31 is electrically connected to the first lower electrode section 220. Accordingly, the first signal wire set 3 is able to couple the first upper electrode section 210 with the first lower electrode section 220. The second signal wire set 4 includes a second high potential voltage wire 40 and a second low potential voltage wire 41. The second high potential voltage wire 40 is electrically connected to the second lower electrode section 221, and the second low potential voltage wire 41 is electrically connected to the second upper electrode section 211. Accordingly, the second signal wire set 4 is able to couple the second upper electrode section 211 with the second lower electrode section 221. In this embodiment, the piezoelectric body 20 is substantially a rectangular structure. The rectangular structure (i.e., the piezoelectric body 20) has a first upper long edge 203, a second upper long edge 204, a first upper short edge 205, a second upper short edge 206, a first lower long edge 207, a second lower long edge 208, a first lower short edge 209 and a second lower short edge 20A, wherein the first upper long edge 203, the second upper long edge 204, the first upper short edge 205 and the second upper short edge 206 define the upper side 201 of the piezoelectric body 20, and the first lower long edge 207, the second lower long edge 208, the first lower short edge 209 and the second lower short edge 20A define the lower side 202 of the piezoelectric body 20.

In this embodiment, the first upper segmenting line 212 connects the first upper short edge 205 and the second upper short edge 206, and the first lower segmenting line 222 connects the first lower short edge 209 and the second lower short edge 20A, i.e., the first upper segmenting line 212 connects the two short edges of the upper side of the rectangular structure (i.e., the piezoelectric body 20), so that the upper electrode 21 is segmented as a top-bottom typed electrode, and the first lower segmenting line 222 connects the two short edges of the lower side of the rectangular structure (i.e., the piezoelectric body 20), so that the lower electrode 22 is segmented as a top-bottom typed electrode. In addition, the first upper segmenting line 212 is substantially perpendicular to the first upper short edge 205 and the second upper short edge 206. The first lower segmenting line 222 is substantially perpendicular to the first lower short edge 209 and the second lower short edge 20A. The first upper segmenting line 212 and the first lower segmenting line 222 are perpendicular to each other.

When the upper electrode 21 and the lower electrode 22 of the piezoelectric material member 2 are subjected to an alternating voltage, the piezoelectric body 20 vibrates due to the converse piezoelectric effect. As shown in FIG. 4, the top-bottom typed piezoelectric material member 2 in this embodiment can preferably be simulated and measured to have three operating frequencies, namely a low frequency F1, an intermediate frequency F2 and a high frequency F3, and impedances of the piezoelectric material member 2 corresponding to the low frequency F1, the intermediate frequency F2 and the high frequency F3 are impedance R1, impedance R2 and impedance R3, respectively. Accordingly, the first high potential voltage wire 30 and the first low potential voltage wire 31 of the first signal wire set 3 is able to apply a first alternating voltage to the top-bottom typed piezoelectric material member 2 in this embodiment, so that the piezoelectric body 20 of the piezoelectric material member 2 generates a first vibration frequency, which may be, for example, the low frequency F1, via the first upper electrode section 210 and the first lower section 220, so as to detect deep defects of the object. In addition, the second high potential voltage wire 40 and the second low potential voltage wire 41 of the second signal wire set 4 is able to apply a second alternating voltage to the top-bottom typed piezoelectric material member 2 in this embodiment, so that the piezoelectric body 20 of the piezoelectric material member 2 generates a second vibration frequency, which may be, for example, the high frequency F2, via the second lower electrode section 221 and the second upper section 211, so as to detect shallow defects of the object. In such a manner, the transducer 1000 of the present invention can simultaneously detect defects in the deep and shallow layers of the object, so as to greatly improve the applicability thereof.

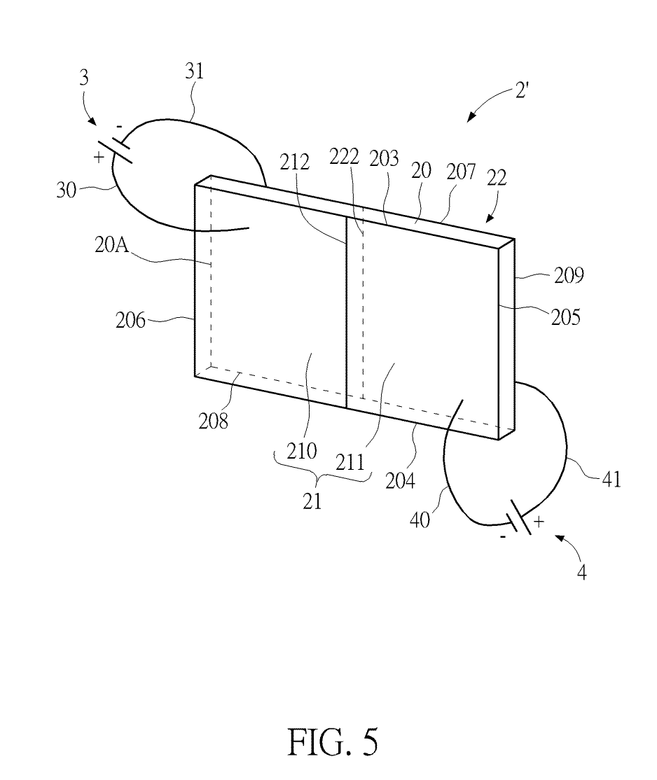

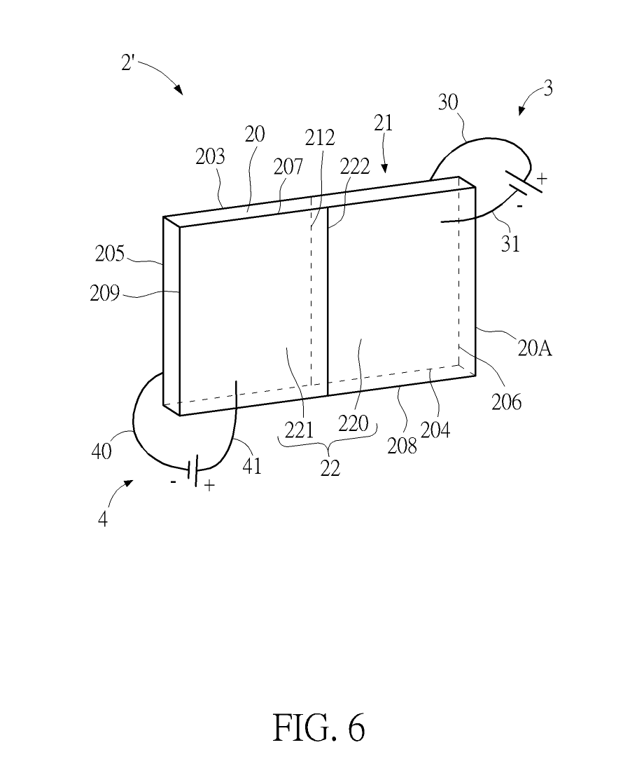

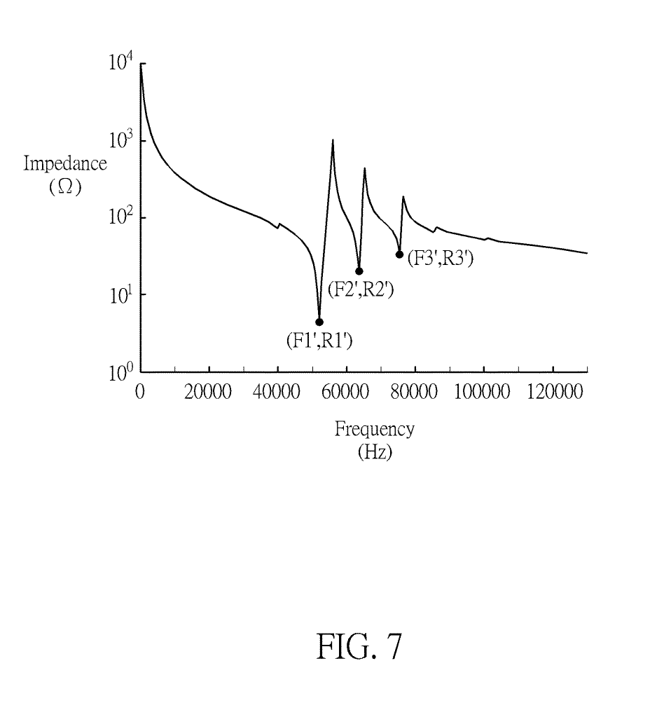

Please refer to FIG. 5 to FIG. 7. FIG. 5 is a diagram of a piezoelectric material member 2′ according to a second embodiment of the present invention. FIG. 6 is a diagram of the piezoelectric material member 2′ in another view according to the second embodiment of the present invention. FIG. 7 is an impedance-frequency diagram of the piezoelectric material member 2′ according to the second embodiment of the present invention. The major difference between the piezoelectric material member 2′ and the aforesaid piezoelectric material member 2 is that the first upper segmenting line 212 of the upper electrode 21 of the piezoelectric material member 2′ connects the first upper long edge 203 and the second upper long edge 204, and the first lower segmenting line 222 of the lower electrode 22 connects the first lower long edge 207 and the second lower long edge 208. The first upper segmenting line 212 is substantially perpendicular to the first upper long edge 203 and the second upper long edge 204, and the first lower segmenting line 222 is substantially perpendicular to the first lower long edge 207 and the second lower long edge 208.

In other words, the first upper segmenting line 212 of the upper electrode 21 of the piezoelectric material member 2′ connects two long edges of the upper side of the rectangular structure(i.e., the piezoelectric body 20), so that the upper electrode 21 is segmented as a left-right typed electrode, and the first lower segmenting line 222 connects the two long edges of the lower side of the rectangular structure (i.e., the piezoelectric body 20), so that the lower electrode 22 is segmented as a left-right typed electrode. As shown in FIG. 7, the left-right typed piezoelectric material member 2′ in this embodiment can preferably be simulated and measured to have three operating frequencies, namely a low frequency F1′, an intermediate frequency F2′ and a high frequency F3′, and impedances of the piezoelectric material member 2′ corresponding to the low frequency F1′, the intermediate frequency F2′ and the high frequency F3′ are impedance R1′, impedance R2′ and impedance R3′, respectively. The working principle of the piezoelectric material member 2′ in this embodiment is the same as that of the piezoelectric material member 2, and further description is omitted herein for simplicity.

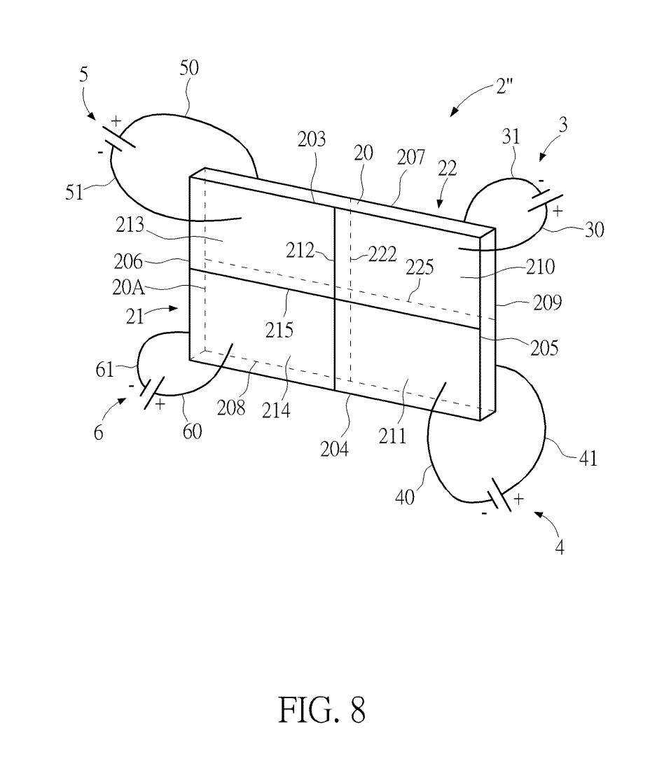

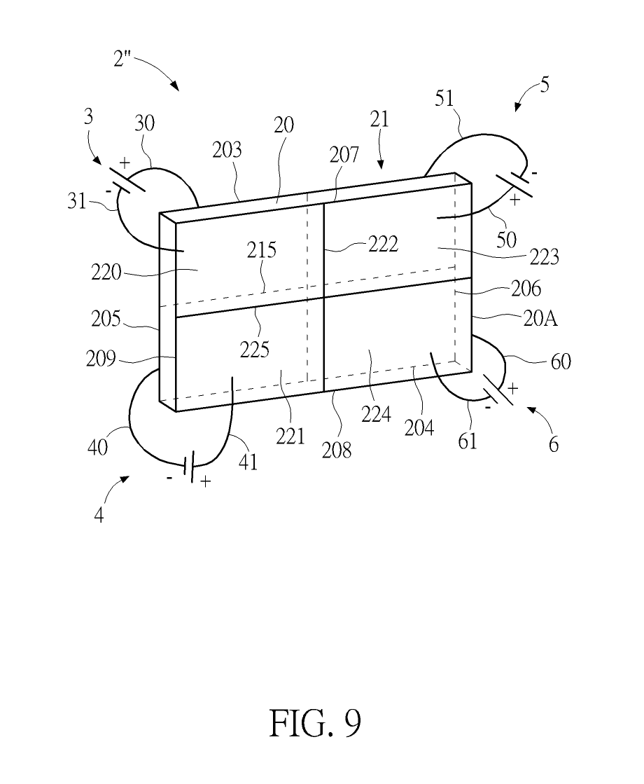

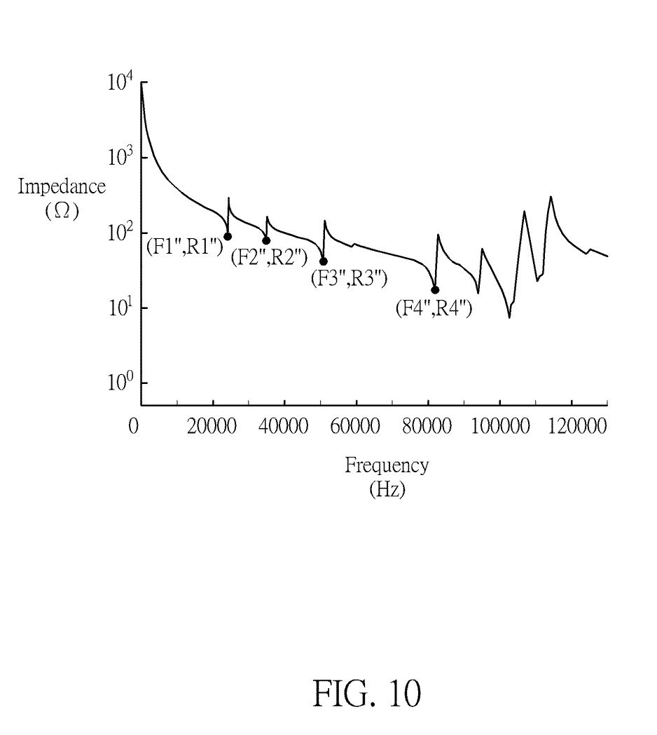

Please refer to FIG. 8 to FIG. 10. FIG. 8 is a diagram of a piezoelectric material member 2″ according to a third embodiment of the present invention. FIG. 9 is a diagram of the piezoelectric material member 2′ in another view according to the third embodiment of the present invention. FIG. 10 is an impedance-frequency diagram of the piezoelectric material member 2″ according to the third embodiment of the present invention. The major difference between the piezoelectric material member 2″ and the aforesaid piezoelectric material member 2 is that the upper electrode 21 of the piezoelectric material member 2′ further has a third upper electrode section 213 and a fourth upper electrode section 214, wherein the first upper electrode section 210, the second upper electrode section 211, the third upper electrode section 213 and the fourth upper electrode section 214 are segmented by the first upper segmenting line 212 and a the second upper segmenting line 215, so that the first upper electrode section 210, the second upper electrode section 211, the third upper electrode section 213 and the fourth upper electrode section 214 are separated from one another. The lower electrode 22 of the piezoelectric material member 2″ further has a third lower electrode section 223 and a fourth lower electrode section 224, wherein the first lower electrode section 220, the second lower electrode section 221, the third lower electrode section 223 and the fourth lower electrode section 224 are segmented by the first lower segmenting line 222 and a second lower segmenting line 225, so that the first lower electrode section 220, the second lower electrode section 221, the third lower electrode section 223 and the fourth lower electrode section 224 are separated from one another. The third lower electrode section 223 corresponds to the third upper electrode section 213, and the fourth lower electrode section 224 corresponds to the fourth upper electrode section 214.

In this embodiment, the first upper segmenting line 212 connects the first upper long edge 203 and the second upper long edge 204, and the second upper segmenting line 215 connects the first upper short edge 205 and the second upper short edge 206. The first lower segmenting line 222 connects the first lower long edge 207 and the second lower long edge 208, and the second lower segmenting line 225 connects the first lower short edge 209 and the second lower short edge 20A. The first upper segmenting line 212 is substantially perpendicular to the first upper long edge 203 and the second upper long edge 204, and the second upper segmenting line 215 is substantially perpendicular to the first upper short edge 205 and the second upper short edge 206. The first lower segmenting line 222 is substantially perpendicular to the first lower long edge 207 and the second lower long edge 208, and the second lower segmenting line 225 is substantially perpendicular to the first lower short edge 209 and the second lower short edge 20A. The first upper segmenting line 212 is substantially perpendicular to the second upper segmenting line 215, and the first lower segmenting line 222 is substantially perpendicular to the second lower segmenting line 225.

In addition, the transducer 1000 further includes further includes a third signal wire set 5 and a fourth signal wire set 6. The third signal wire set 5 includes a third high potential voltage wire 50 and a third low potential voltage wire 51. The fourth signal wire set 6 includes a fourth high potential voltage wire 60 and a the fourth low potential voltage wire 61. The third high potential voltage wire 50 is electrically connected to the third lower electrode section 223, and the third low potential voltage wire 51 is electrically connected to the third upper electrode section 213. Accordingly, the third signal wire set 5 is able to couple the third upper electrode section 213 and the third lower electrode section 223. The fourth high potential voltage wire 60 is electrically connected to the fourth upper electrode section 214, and the fourth low potential voltage wire 61 is electrically connected to the fourth lower electrode section 224. Accordingly, the fourth signal wire set 6 is able to couple the fourth upper electrode section 214 and the fourth lower electrode section 224.

As mentioned above, the first upper segmenting line 212 of the upper electrode 21 of the piezoelectric material member 2″ connects the two long edges of the upper side of the rectangular structure (i.e., the piezoelectric body 20), and the second upper segmenting line 215 connects the two short edges of the upper side of the rectangular structure (i.e., the piezoelectric body 20). Accordingly, the first upper segmenting line 212 and the second upper segmenting line 215 segment the upper electrode 21 as a cross-typed electrode. The first lower segmenting line 222 of the lower electrode 22 of the piezoelectric material member 2′ connects the two long edges of the lower side of the rectangular structure (i.e., the piezoelectric body 20), and the second lower segmenting line 225 connects the two short edges of the lower side of the rectangular structure (i.e., the piezoelectric body 20). Accordingly, the first lower segmenting line 222 and the second lower segmenting line 225 segment the lower electrode 22 as a cross-typed electrode. As shown in FIG. 10, the cross-typed piezoelectric material member 2″ in this embodiment can preferably be simulated and measured to have three operating frequencies, namely a low frequency F1″, an intermediate frequency F2′ and a high frequency F3″, and impedances of the piezoelectric material member 2″ corresponding to the low frequency F1″, the intermediate frequency F2″ and the high frequency F3″ are impedance R1″, impedance R2″ and impedance R3″, respectively. The working principle of the piezoelectric material member 2″ in this embodiment is the same as that of the piezoelectric material member 2, and further description is omitted herein for simplicity.

Compared to the prior art, the present invention may apply a first alternating voltage to the first upper electrode section and the first lower electrode section of the piezoelectric material member via the first signal wire set, so that the piezoelectric body of the piezoelectric material member generates the first frequency (e.g., a low frequency) via the first lower electrode section and the first upper electrode section for detecting deep defects of a detected object. In addition, the present invention may apply a second alternating voltage to the second upper electrode section and the second lower electrode section of the piezoelectric material member via the second signal wire set, so that the piezoelectric body of the piezoelectric material member generates the second frequency (e.g., a high frequency) via the second lower electrode section and the second upper electrode section for detecting shallow defects of the detected object. As a result, the transducer of the present invention can simultaneously detect the deep and shallow defects of the detected object, which results in greatly enhancement of the applicability of the transducer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A piezoelectric material member capable of generating different vibration frequencies, comprising:
a piezoelectric body having an upper side and a lower side opposite to the upper side;
an upper electrode disposed on the upper side, the upper electrode having a first upper electrode section and a second upper electrode section separated from the first upper electrode section; and
a lower electrode disposed on the lower side, the lower electrode having a first lower electrode section and a second lower electrode section separated from the first lower electrode section, the first lower electrode section being coupled to the first upper electrode section, so that the piezoelectric body generates a first frequency via the first lower electrode section and the first upper electrode section, the second lower electrode section being coupled to the second upper electrode section, so that the piezoelectric body generates a second frequency via the second lower electrode section and the second upper electrode section.

2. The piezoelectric material member of claim 1, wherein the first upper electrode section and the second upper electrode section are segmented by a first upper segmenting line, and the first lower electrode section and the second lower electrode section are segmented by a first lower segmenting line.

3. The piezoelectric material member of claim 2, wherein the piezoelectric body is substantially a rectangular structure, the rectangular structure has a first upper long edge, a second upper long edge, a first upper short edge, a second upper short edge, a first lower long edge, a second lower long edge, a first lower short edge and a second lower short edge, the first upper long edge, the second upper long edge, the first upper short edge and the second upper short edge define the upper side, the first lower long edge, the second lower long edge, the first lower short edge and the second lower short edge define the lower side, the first upper segmenting line connects the first upper short edge and the second upper short edge, and the first lower segmenting line connects the first lower short edge and the second lower short edge.

4. The piezoelectric material member of claim 3, wherein the first upper segmenting line is substantially perpendicular to the first upper short edge and the second upper short edge, and the first lower segmenting line is substantially perpendicular to the first lower short edge and the second lower short edge.

5. The piezoelectric material member of claim 2, wherein the piezoelectric body is substantially a rectangular structure, the rectangular structure has a first upper long edge, a second upper long edge, a first upper short edge, a second upper short edge, a first lower long edge, a second lower long edge, a first lower short edge and a second lower short edge, the first upper long edge, the second upper long edge, the first upper short edge and the second upper short edge define the upper side, the first lower long edge, the second lower long edge, the first lower short edge and the second lower short edge define the lower side, the first upper segmenting line connects the first upper long edge and the second upper long edge, and the first lower segmenting line connects the first lower long edge and the second lower long edge.

6. The piezoelectric material member of claim 5, wherein the first upper segmenting line is substantially perpendicular to the first upper long edge and the second upper long edge, and the first lower segmenting line is substantially perpendicular to the first lower long edge and the second lower long edge.

7. The piezoelectric material member of claim 1, wherein the upper electrode further has a third upper electrode section and a fourth upper electrode section, the first upper electrode section, the second upper electrode section, the third upper electrode section and the fourth upper electrode section are separated from one another, the lower electrode further has a third lower electrode section and a fourth lower electrode section, the first lower electrode section, the second lower electrode section, the third lower electrode section and the fourth lower electrode section are separated from one another, the third lower electrode section is coupled to the third upper electrode section, so that the piezoelectric body generates a third frequency via the third lower electrode section and the third upper electrode section, the fourth lower electrode section is coupled to the fourth upper electrode section, so that the piezoelectric body generates a fourth frequency via the fourth lower electrode section and the fourth upper electrode section.

8. The piezoelectric material member of claim 7, wherein the first upper electrode section, the second upper electrode section, the third upper electrode section and the fourth upper electrode section are segmented by a first upper segmenting line and a second upper segmenting line, and the first lower electrode section, the second lower electrode section, the third lower electrode section and the fourth lower electrode section are segmented by a first lower segmenting line and a second lower segmenting line.

9. The piezoelectric material member of claim 8, wherein the piezoelectric body is substantially a rectangular structure, the rectangular structure has a first upper long edge, a second upper long edge, a first upper short edge, a second upper short edge, a first lower long edge, a second lower long edge, a first lower short edge and a second lower short edge, the first upper long edge, the second upper long edge, the first upper short edge and the second upper short edge define the upper side, the first lower long edge, the second lower long edge, the first lower short edge and the second lower short edge define the lower side, the first upper segmenting line connects the first upper long edge and the second upper long edge, the second upper segmenting line connects the first upper short edge and the second upper short edge, the first lower segmenting line connects the first lower long edge and the second lower long edge, the second lower segmenting line connects the first lower short edge and the second lower short edge.

10. The piezoelectric material member of claim 9, wherein the first upper segmenting line is substantially perpendicular to the first upper long edge and the second upper long edge, the second upper segmenting line is substantially perpendicular to the first upper short edge and the second upper short edge, the first lower segmenting line is substantially perpendicular to the first lower long edge and the second lower long edge, the second lower segmenting line is substantially perpendicular to the first lower short edge and the second lower short edge, the first upper segmenting line is substantially perpendicular to the second upper segmenting line, and the first lower segmenting line is substantially perpendicular to the second lower segmenting line.

11. A transducer, comprising:
a housing;
a piezoelectric material member disposed inside the housing and comprising:
a piezoelectric body having an upper side and a lower side opposite to the upper side;
an upper electrode disposed on the upper side, the upper electrode having a first upper electrode section and a second upper electrode section separated from the first upper electrode section; and
a lower electrode disposed on the lower side, the lower electrode having a first lower electrode section and a second lower electrode section separated from the first lower electrode section, the first lower electrode section corresponding to the first upper electrode section, the second lower electrode section corresponding to the second upper electrode section;
a first signal wire set coupled to the first upper electrode section and the first lower electrode section, so that the piezoelectric body generates a first frequency via the first lower electrode section and the first upper electrode section; and
a second signal wire set coupled to the second upper electrode section and the second lower electrode section, so that the piezoelectric body generates a second frequency via the second lower electrode section and the second upper electrode section.

12. The transducer of claim 11, wherein the first signal wire set comprises a first high potential voltage wire and a first low potential voltage wire, the first high potential voltage wire is electrically connected to the first upper electrode section, the first low potential voltage wire is electrically connected to the first lower electrode section, the second signal wire set comprises a second high potential voltage wire and a second low potential voltage wire, the second high potential voltage wire is electrically connected to the second lower electrode section, the second low potential voltage wire is electrically connected to the second upper electrode section.

13. The transducer of claim 11, wherein the first upper electrode section and the second upper electrode section are segmented by a first upper segmenting line, the first lower electrode section and the second lower electrode section are segmented by a first lower segmenting line, the piezoelectric body is substantially a rectangular structure, the rectangular structure has a first upper long edge, a second upper long edge, a first upper short edge, a second upper short edge, a first lower long edge, a second lower long edge, a first lower short edge, a second lower short edge, the first upper long edge, the second upper long edge, the first upper short edge and the second upper short edge define the upper side, the first lower long edge, the second lower long edge, the first lower short edge and the second lower short edge define the lower side, the first upper segmenting line connects the first upper short edge and the second upper short edge, and the first lower segmenting line connects the first lower short edge and the second lower short edge, the first upper segmenting line is substantially perpendicular to the first upper short edge and the second upper short edge, the first lower segmenting line is substantially perpendicular to the first lower short edge and the second lower short edge.

14. The transducer of claim 11, wherein the first upper electrode section and the second upper electrode section are segmented by a first upper segmenting line, the first lower electrode section and the second lower electrode section are segmented by a first lower segmenting line, the piezoelectric body is substantially a rectangular structure, the rectangular structure has a first upper long edge, a second upper long edge, a first upper short edge, a second upper short edge, a first lower long edge, a second lower long edge, a first lower short edge, a second lower short edge, the first upper long edge, the second upper long edge, the first upper short edge and the second upper short edge define the upper side, the first lower long edge, the second lower long edge, the first lower short edge and the second lower short edge define the lower side, the first upper segmenting line connects the first upper long edge and the second upper long edge, and the first lower segmenting line connects the first lower long edge and the second lower long edge, the first upper segmenting line is substantially perpendicular to the first upper long edge and the second upper long edge, the first lower segmenting line is substantially perpendicular to the first lower long edge and the second lower long edge.

15. The transducer of claim 11, wherein the upper electrode further has a third upper electrode section and a fourth upper electrode section, the first upper electrode section, the second upper electrode section, the third upper electrode section and the fourth upper electrode section are separated from one another, the lower electrode further has a third lower electrode section and a fourth lower electrode section, the first lower electrode section, the second lower electrode section, the third lower electrode section and the fourth lower electrode section are separated from one another, the third lower electrode section corresponds to the third upper electrode section, the fourth lower electrode section corresponds to the fourth upper electrode section, and the probe structure further comprises:
a third signal wire set coupled to the third upper electrode section and the third lower electrode section, so that the piezoelectric body generates a third frequency via the third lower electrode section and the third upper electrode section; and
a fourth signal wire set coupled to the fourth upper electrode section and the fourth lower electrode section, so that the piezoelectric body generates a fourth frequency via the fourth lower electrode section and the fourth upper electrode section.

16. The transducer of claim 15, wherein the third signal wire set comprises a third high potential voltage wire and a third low potential voltage wire, the third high potential voltage wire is electrically connected to the third lower electrode section, the third low potential voltage wire is electrically connected to the third upper electrode section, the fourth signal wire set comprises a fourth high potential voltage wire and a fourth low potential voltage wire, the fourth high potential voltage wire is electrically connected to the fourth upper electrode section, the fourth low potential voltage wire is electrically connected to the fourth lower electrode section.

17. The transducer of claim 15, wherein the first upper electrode section, the second upper electrode section, the third upper electrode section and the fourth upper electrode section are segmented by a first upper segmenting line and a second upper segmenting line, and the first lower electrode section, the second lower electrode section, the third lower electrode section and the fourth lower electrode section are segmented by a first lower segmenting line and a second lower segmenting line, the piezoelectric body is substantially a rectangular structure, the rectangular structure has a first upper long edge, a second upper long edge, a first upper short edge, a second upper short edge, a first lower long edge, a second lower long edge, a first lower short edge, a second lower short edge, the first upper long edge, the second upper long edge, the first upper short edge and the second upper short edge define the upper side, the first lower long edge, the second lower long edge, the first lower short edge and the second lower short edge define the lower side, the first upper segmenting line connects the first upper long edge and the second upper long edge, the second upper segmenting line connects the first upper short edge and the second upper short edge, the first lower segmenting line connects the first lower long edge and the second lower long edge, the second lower segmenting line connects the first lower short edge and the second lower short edge.

18. The transducer of claim 17, wherein the first upper segmenting line is substantially perpendicular to the first upper long edge and the second upper long edge, the second upper segmenting line is substantially perpendicular to the first upper short edge and the second upper short edge, the first lower segmenting line is substantially perpendicular to the first lower long edge and the second lower long edge, the second lower segmenting line is substantially perpendicular to the first lower short edge and the second lower short edge, the first upper segmenting line is substantially perpendicular to the second upper segmenting line, and the first lower segmenting line is substantially perpendicular to the second lower segmenting line.

19. The transducer of claim 11, further comprising:
a gel body disposed inside the housing and for fixing the piezoelectric material member, the first signal wire set and the second signal wire set inside the housing.

20. The transducer of claim 11, further comprising a covering layer for covering the housing.
